(19) United States
(12) Patent Application Publication
(10) Pub. No.: US 2015/0096802 A1
(43) Pub. Date: Apr. 9, 2015

(54) WIRE HARNESS

(71) Applicants: AUTONETWORKS TECHNOLOGIES, LTD, Yokkaichi, Mie (JP); SUMITOMO WIRING SYSTEMS, LTD., Yokkaichi, Mie (JP); SUMITOMO ELECTRIC INDUSTRIES, LTD., Osaka-shi, Osaka (JP)

(72) Inventors: Yasushi Itani, Yokkaichi (JP); Fujio Sonoda, Yokkaichi (JP); Naoki Aoyama, Yokkaichi (JP); Yuichi Kimoto, Yokkaichi (JP); Yoshinori Sugimoto, Yokkaichi (JP)

(21) Appl. No.: 14/394,849

(22) PCT Filed: Dec. 21, 2012
(86) PCT No.: PCT/JP2012/083229

§ 371 Date: Oct. 16, 2014

(30) Foreign Application Priority Data
Apr. 25, 2012 (JP) 2012-099329

(51) Int. Cl. B60R 16/02; H05K 9/00

(52) U.S. Cl. CPC B60R 16/0215; H05K 9/00
USPC 174/72 A

(57) ABSTRACT

A wire harness includes first, second and third power cables, first, second and third conductive electromagnetic shielding members, and an intermediate short-circuit member. The power cables are arranged to conduct symmetrical three-phase AC electricity. The conductive electromagnetic shielding members are arranged in parallel to each other and spaced apart from each other, each of the conductive electromagnetic shielding members disposed surrounding respective ones of the power cables. The intermediate short-circuit member is arranged to electrically connect the electromagnetic shielding members to one another in at least one intermediate region between first and second longitudinal ends of each of the electromagnetic shielding members. The intermediate short-circuit member has a conductive member arranged to electrically connect the electromagnetic shielding members to one another, and a nonconductive armoring section arranged to cover an outer surface of the conductive member.

This application is a national stage application of PCT/JP2012/083229, international filing date Dec. 21, 2012, and claims priority to JP 2012-099329, filed in Japan on Apr. 25, 2012, the entire disclosures of which are hereby incorporated by reference in their entirety.

### BACKGROUND

The present invention relates to a wire harness including conductive electromagnetic shielding members that surround electric wires.

Conventionally, some wire harnesses that are laid in a vehicle such as an automobile may include a conductive electromagnetic shielding member that surrounds electric wires to shield them from an electromagnetic noise wave. The electric wires that are passed through the hollow section of the electromagnetic shielding member are typically unshielded electric wires. “Unshielded electric wire” refers to an insulating electric wire that is not covered with an electromagnetic shielding member such as a braided wire.

For example, as disclosed in Japanese Patent Application Publication No. 2006-344398 A, a wire harness for vehicles may include a braided wire, serving as an electromagnetic shielding member, that is made from metal wires braided into a tubular shape. The braided wire is a tubular electromagnetic shielding member that is deformable according to deformation of electric wires.

Furthermore, as disclosed in Japanese Patent Application Publication No. 2011-193677 A, a wire harness that is laid at a position exposed to the outside of an automobile, such as the lower surface (under the floor) of the bottom plate, may include an electric wire protection pipe that is a tubular metal member surrounding electric wires. The electric wire protection pipe can serve not only as a member for protecting the electric wires from foreign objects such as flying gravel from the road but also as an electromagnetic shielding member for shielding the electric wires from an electromagnetic noise wave.

In the wire harness including the electromagnetic shielding member, both ends of the electric wires may be routed into metal casings through openings in the casings, the casings accommodating counterpart devices to which the electric wires are connected, and two ends of the electromagnetic shielding member may be electrically connected to the metal casings. Furthermore, the metal casings may be electrically connected to a reference potential body, such as an automobile body. Accordingly, the electromagnetic shielding member and the reference potential body may form, together with other conductive members such as the casings, a closed loop.

If the electric wires surrounded by the electromagnetic shielding member are power cables that transmit an alternating current, an electromagnetic induction current flows through the closed loop formed by the electromagnetic shielding member and the reference potential body. Furthermore, the electromagnetic induction current flowing through the electromagnetic shielding member increases with an increase in the current value and the frequency of the alternating currents flowing through the power cables.

Meanwhile, electrically-driven vehicles such as electric cars and hybrid cars employ a three-phase motor, and a wire harness that is connected to the three-phase motor may include three power cables for conducting symmetrical three-phase alternating-current (AC) electricity. In this case, phase shifts of the electromagnetically induced electricity caused by the AC currents of the respective phases are the same. Note that, in the following description, unless explained otherwise, the term “three-phase alternating current” refers to a symmetrical three-phase alternating current, that is, a three-phase alternating current whose phases are shifted by the same degree (120 degrees, for example).

When the three power cables for conducting three-phase AC electricity are surrounded altogether by a single electromagnetic shielding member, alternating currents having different phases that respectively flow through the three power cables may cause electromagnetic induction in the single electromagnetic shielding member. Therefore, the AC currents of the three different phases generated by the electromagnetic induction can be overlapped and cancelled out in the single electromagnetic shielding member.

On the other hand, when the three power cables for conducting three-phase AC electricity are respectively surrounded by three electromagnetic shielding members, alternating currents having different phases that respectively flow through the three power cables may cause electromagnetic induction in the respective electromagnetic shielding members. For the sake of convenience of routing, a wire harness may be needed to include three electromagnetic shielding members that respectively surround three power cables for conducting three-phase AC electricity.

### SUMMARY

Recently, in electrically-driven vehicles such as electric cars and hybrid cars, high-power and high-frequency AC electricity is supplied to a three-phase motor from an inverter circuit. Therefore, when a wire harness includes three electromagnetic shielding members that respectively surround three power cables for conducting three-phase AC electricity, an excessive electromagnetic induction current is likely to flow through each electromagnetic shielding member. Also in a case of an elongated power cable and an elongated electromagnetic shielding member, an excessive electromagnetic induction current is likely to flow through each electromagnetic shielding member.

When an excessive electromagnetic induction current flows through the electromagnetic shielding member, this causes the problem that members arranged in the periphery of the electromagnetic shielding member are damaged by heat generated by the electromagnetic shielding member.

It is an object of the present invention to prevent an excessive electromagnetic induction current from flowing through each electromagnetic shielding member, when three power cables for conducting symmetrical three-phase AC electricity are respectively surrounded by three electromagnetic shielding members.

A wire harness according to a first aspect may include, for example, the following constituent components: (1) as first constituent components, first, second and third power cables arranged to conduct symmetrical three-phase AC electricity; (2) as second constituent components, first, second and third conductive electromagnetic shielding members arranged in parallel to each other and spaced apart from each other, each of the first, second and third conductive electromagnetic shielding members disposed surrounding respective ones of the first, second and third power cables: and (3) as third constituent components, an intermediate short-circuit member arranged to electrically connect the first, second and third electromagnetic shielding members to one another in at least one intermediate region between first and second longitudinal ends of each of the electromagnetic shielding members. The intermediate short-circuit member has a conductive member arranged to electrically connect the first, second and third electromagnetic shielding members to one another, and a nonconductive armoring section arranged to cover an outer surface of the conductive member.

A wire harness according to a second aspect relates to one aspect of the wire harness according to the first aspect. In the wire harness according to the second aspect, the conductive member of the intermediate short-circuit member is a conductive clamping section that clamps the three electromagnetic shielding members altogether in the intermediate region.

A wire harness according to a third aspect relates to one aspect of the wire harness according to the second aspect. The wire harness according to the third aspect may further include a nonconductive fastener that is connected to the intermediate short-circuit member. The fastener can be fixed to a rim portion of a through hole of a plate-like supporting member, for example.

In the wire harnesses according to the first to third aspects, the three power cables for conducting symmetrical three-phase AC electricity are respectively surrounded by the three electromagnetic shielding members. Therefore, alternating currents having different phases that flow through the respective three power cables may cause electromagnetic induction in the respective electromagnetic shielding member. However, the three electromagnetic shielding members are electrically connected to one another in at least one intermediate region of the electromagnetic shielding members by the intermediate short-circuit member. Therefore, in each electromagnetic shielding member, currents of the three different phases generated by the electromagnetic induction are overlapped and cancelled out. As a result, an excessive electromagnetic induction current is prevented from flowing through the electromagnetic shielding member.

Furthermore, in the wire harness according to the second aspect, the three electromagnetic shielding members may be held by the clamping section of the intermediate short-circuit member in the state in which the electromagnetic shielding members are arranged in parallel to each other and spaced apart from each other. This can prevent the problem that the three electromagnetic shielding members come too close to each other in regions other than the intermediate regions in which the intermediate short-circuit member is provided, thereby causing a spark discharge. Furthermore, the intermediate short-circuit member also functions as a spacer for maintaining a distance among the three electromagnetic shielding members. This thus brings about an effect that the number of the constituent components is reduced. Moreover, in contrast to the case where electromagnetic shielding members are inserted into a tubular member from their ends, the clamping section of the intermediate short-circuit member can easily be mounted to the intermediate regions of the electromagnetic shielding members.

Furthermore, the wire harness according to the third aspect may include a nonconductive fastener that is connected to the intermediate short-circuit member. Therefore, in the step in which the wire harness is laid in a vehicle, fixing the intermediate regions of the three electromagnetic shielding members to the supporting member such as a body of the vehicle is easily achieved.

### BRIEF DESCRIPTION OF THE DRAWINGS

FIG. 1 is a perspective view illustrating one example of a wire harness according to a first embodiment.

FIG. 2 is a plan view illustrating the wire harness laid in a vehicle.

FIG. 3 is an exploded perspective view illustrating an intermediate short-circuit member included in the wire harness.

FIG. 4 is an exploded perspective view illustrating the main part of a wire harness according to a second embodiment.

FIG. 5 is an exploded perspective view illustrating the main part of a wire harness according to a third embodiment.

### DETAILED DESCRIPTION OF EMBODIMENTS

Hereinafter, illustrative embodiments of the present invention will be described with reference to the accompanying drawings. The following embodiments are specific examples of the present invention and are not intended to restrict the technical scope of the present invention.

### First Embodiment

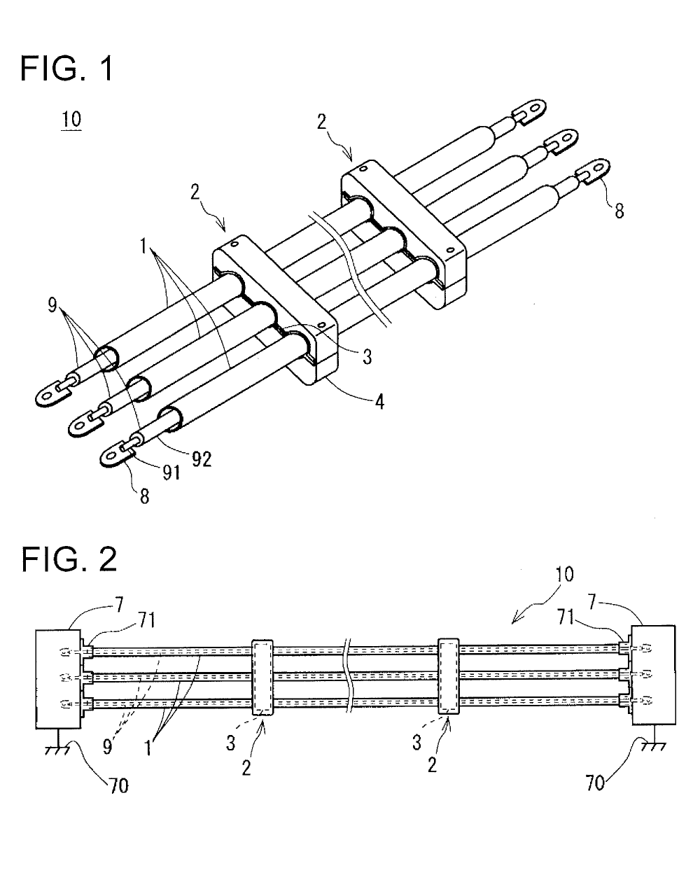

First, a wire harness 10 and an intermediate short-circuit member 2 included therein according to the first embodiment will be described with reference to FIGS. 1 to 3. As shown in FIGS. 1 and 2, the wire harness 10 includes at least three power cables 9, at least three electromagnetic shielding members 1, and at least one intermediate short-circuit member 2.

### <Power Cable>

Each power cable 9 is an insulating electric wire that is constituted by a core wire 91 made from a conductive material, and an insulating coating 92 that is made from an insulating material and covers the periphery of the core wire 91. Terminal metal fittings 8, for example, are connected to the core wires 91 at end sections of the power cables 9. Note that, in the example shown in FIGS. 1 and 2, the wire harness 10 includes three power cables 9 that are arranged in parallel to each other. However, the wire harness 10 may include two or more sets of three power cables 9.

Furthermore, it is also possible that the wire harness 10 further includes cable holding members for holding ends of the three power cables 9 in a given positional relationship. In this case, the cable holding members hold ends of the three power cables 9 arranged parallel to each other in a given positional relationship, and electrically insulate the three power cables 9 from one another. For example, the cable holding members may be members made from a nonconductive synthetic resin. In this case, the cable holding members may be members that are molded by insert molding in which the plurality of power cables 9 serve as insert members.

### <Electromagnetic Shielding Member>

The electromagnetic shielding members 1 are conductive members that are arranged in parallel to each other and spaced apart from each other, and respectively surround the power cables 9. Therefore, the wire harness 10 includes the same number of the electromagnetic shielding members 1 as power cables 9. In the example shown in FIGS. 1 and 2, the wire harness 10 includes three electromagnetic shielding members 1 that are arranged in parallel to each other. However, the wire harness 10 may include two or more sets of three electromagnetic shielding members 1, depending on the number of power cables 9.

For example, each of the electromagnetic shielding members 1 may be a metal pipe member that surrounds one of the power cables 9. In this case, the pipe member may be made from, for example, a material constituted mainly by metal such as iron, stainless steel, or aluminum. A plated layer or a layer of paint in an area that does not come into contact with the intermediate short-circuit members 2 may be formed on the surface of the pipe member as needed.

Furthermore, the electromagnetic shielding member 1 may be a braided wire that is made from metal wires braided into a tubular shape. In this case, the braided wire may be made from wires constituted mainly by metal such as copper, stainless steel, or aluminum.

Furthermore, a metal cloth, which is a fabric woven with metallic yarn, may be used as the electromagnetic shielding member 1. In this case, the metal cloth is wound around the power cable 9 and formed into a tubular shape.

The metal cloth may be a cloth having a mesh structure woven by metallic yarn being crossed in the longitudinal direction and the lateral direction, the metallic yarns being made mainly from copper, for example. Furthermore, the metal cloth may have a structure in which a flexible film made from a resin material is adhered to the cloth woven with the metallic yarn. An electromagnetic shielding member 1 that is made from a braided wire or a metal cloth has conductivity and flexibility.

As shown in FIG. 2 for example, in the state in which the wire harness 10 is laid in a vehicle, both ends of the power cables 9 are routed into metal casings 7 accommodating counterpart devices to which the power cables 9 are connected from openings of the casings 7. Furthermore, both ends of the electromagnetic shielding members 1 are electrically connected to the metal casings 7.

In the example shown in FIG. 2, the electromagnetic shielding members 1 and the casings 7 are connected to each other by connecting metal fittings 71. However, the structure for connecting them is not limited to the connecting metal fittings 71. Furthermore, the metal casings 7 are electrically connected to a reference potential body 70 such as an automobile body. Accordingly, the electromagnetic shielding members 1 and the reference potential body 70 form, together with other conductive members such as the casings 7, a closed loop.

### <Intermediate Short-Circuit Member>

The intermediate short-circuit members 2 are each an example of members that electrically connect the three electromagnetic shielding members 1 to one another in at least one intermediate region between the two longitudinal ends of the electromagnetic shielding members 1. In the example shown in FIGS. 1 and 2, two intermediate short-circuit members 2 are provided at two intermediate regions of the three electromagnetic shielding members 1 that are arranged in parallel to each other. However, it is also possible that the wire harness 10 includes only one intermediate short-circuit member 2 or three or more intermediate short-circuit members 2.

The intermediate short-circuit members 2 of the present embodiment each have a clamping section 3 and an armoring section 4. The clamping section 3 is made from a conductive member that clamps the three electromagnetic shielding members 1 altogether in their intermediate regions. The clamping section 3 is a metal fitting made from, for example, a material constituted mainly by metal such as iron, stainless steel, or aluminum. Note that it is preferable that the clamping section 3 be made from a material of the same type as a conductive material from which the electromagnetic shielding members 1 are made.

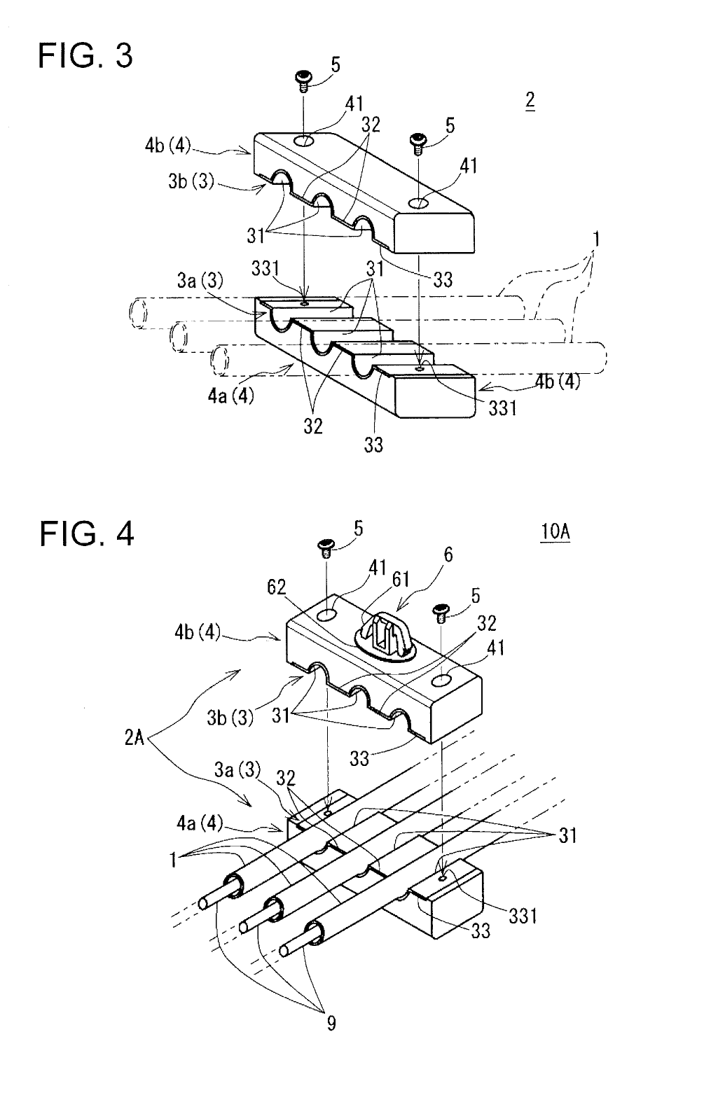

As shown in FIG. 3, the clamping section 3 is constituted by a first clamping member 3a and a second clamping member 3b that are mounted to clamp the three electromagnetic shielding members 1 in their respective intermediate regions. Note that, in FIG. 3, the electromagnetic shielding members 1 are indicated by phantom lines (the long-short dashed lines).

Furthermore, the first clamping member 3a and the second clamping member 3b have each three grooves 31, two linking sections 32 that connect the three grooves 31, and two connecting sections 33 that are formed at both ends with respect to the direction in which the three grooves 31 are lined up.

The grooves 31 are groove-shaped sections into which the three electromagnetic shielding members 1 surrounding the respective three power cables 9 are respectively fitted. The electromagnetic shielding members 1 are sandwiched between the grooves 31 of the first clamping member 3a and the grooves 31 of the second clamping member 3b. By this arrangement, the electromagnetic shielding members 1 and the grooves 31 are electrically connected to each other.

The linking sections 32 are sections by which the three grooves 31 are spaced apart from each other in a given positional relationship, and that electrically connect the three grooves 31 to one another.

Furthermore, the first clamping member 3a and the second clamping member 3b are connected to each other by connectors while sandwiching the three electromagnetic shielding members 1 that are spaced apart from each other. By this arrangement, the first clamping member 3a and the second clamping member 3b are maintained in the assembled state. In the example shown in FIG. 3, the connectors are screws 5.

The connecting sections 33 are sections to which the connectors for connecting the first clamping member 3a and the second clamping member 3b are fixed. In the example shown in FIG. 3, the connecting sections 33 are sections that each have a screw hole 331 into which the connecting screw 5 is tightened.

Furthermore, the armoring section 4 is a nonconductive member that covers the outer surfaces of the clamping section 3. In the present embodiment, the armoring section 4 is constituted by a first armoring member 4a that covers the outer surface of the first clamping member 3a, and a second armoring member 4b that covers the outer surface of the second clamping member 3b.

For example, the armoring section 4 is a member molded from a synthetic resin. In this case, the armoring section 4 is made from a material such as polypropylene (PP), polyethylene (PE), polyvinyl chloride (PVC), polyethylene terephthalate (PET), or polyamide (PA). Furthermore, the first armoring member 4a is formed as one piece with the first clamping member 3a by, for example, two-color molding. Similarly, the second armoring member 4b as well is formed as one piece with the second clamping member 3b.

By the intermediate short-circuit member 2 including the armoring section 4, the intermediate regions of the electromagnetic shielding members 1 are prevented from coming too close to or coming into contact with conductive members in the periphery, such as the automobile body or the like, when the wire harness 10 is laid in a vehicle. That is, the armoring section 4 functions as a spacer for electrically insulating the electromagnetic shielding members 1 from surrounding members.

In the example shown in FIG. 3, each of the first armoring member 4a and the second armoring member 4b has through holes 41 into which the screws 5 serving as connectors are inserted. The through holes 41 communicate with the screw holes 331 of the connecting section 33.

### <Effects>

In the wire harness 10, the three power cables 9 for conducting symmetrical three-phase AC electricity are respectively surrounded by the three electromagnetic shielding members 1. Therefore, alternating currents having respective phases that flow through the respective three power cables 9 cause electromagnetic induction in the respective electromagnetic shielding members 1.

However, the three electromagnetic shielding members 1 are electrically connected to one another in at least one intermediate region of the electromagnetic shielding members by the intermediate short-circuit member 2. Therefore, in the electromagnetic shielding members 1, the currents of the three different phases generated by the electromagnetic induction are overlapped and cancelled out. As a result, an excessive electromagnetic induction current is prevented from flowing through the electromagnetic shielding member 1.

Furthermore, in the wire harness 10, the three electromagnetic shielding members 1 are held in a state in which they are arranged in parallel to each other and spaced apart, by the clamping section 3 of the intermediate short-circuit member 2. This can prevent the problem that the three electromagnetic shielding members 1 come too close to each other in regions other than the intermediate regions in which the intermediate short-circuit member 2 is provided, thereby causing a spark discharge.

Furthermore, the intermediate short-circuit member 2 also functions as a spacer for maintaining a distance among the three electromagnetic shielding members 1. This brings about the effect that the number of constituent components is reduced. Moreover, in contrast to the case where electromagnetic shielding members 1 are inserted into a tubular member from their ends, the clamping section 3 of the intermediate short-circuit member 2 can easily be mounted to the intermediate regions of the electromagnetic shielding members 1.

### Second Embodiment

The following will describe a wire harness 10A and an intermediate short-circuit member 2A included therein according to a second embodiment with reference to FIG. 4. Note that FIG. 4 is an exploded perspective view illustrating the main part of the wire harness 10A. In FIG. 4, the same reference numerals are given to the same constituent components as those shown in FIGS. 1 to 3. Hereinafter, only differences between the wire harness 10A and the wire harness 10 will be explained.

Like the wire harness 10, the wire harness 10A includes three power cables 9, three electromagnetic shielding members 1 that respectively surround the power cables 9, and at least one intermediate short-circuit member 2A.

The intermediate short-circuit member 2A has a configuration in which a fastener 6 is added to the intermediate short-circuit member 2. The fastener 6 is a well-known fixture that is fixed to the rim portion of a through hole formed in a plate-like supporting member such as a body panel of the vehicle. The fastener 6 is made from a nonconductive material, and is connected to the intermediate short-circuit member 2 and formed as one piece therewith.

The fastener 6 is, for example, a member molded from a synthetic resin. In this case, the fastener 6 is made from a material such as polypropylene (PP), polyethylene (PE), polyvinyl chloride (PVC), polyethylene terephthalate (PET), or polyamide (PA).

The fastener 6 has an inserted section 61, which is inserted into a mounting hole serving as a through hole of the plate member, and a flange section 62, to which the armoring section 4 is fixed. The fastener 6 sandwiches the rim portion of the mounting hole between the inserted section 61 and the flange section 62.

The armoring section 4 is fixed to one surface of the flange section 62, and the inserted section 61 is provided on the other surface so as to project therefrom. The flange section 62 is formed in a plate shape having a larger area than the area of the mounting hole, thereby covering the mounting hole.

When the inserted section 61 is inserted into the mounting hole, projecting sections of the inserted section 61 that are formed on its two sides come into contact with the rim portion of the mounting hole and are pressed, shrinking to the width of the mounting hole. When the inserted section 61 is further inserted into the mounting hole, the projecting sections formed on both sides of the inserted section 61 return to a shape having a width larger than that of the mounting hole on the back side of the mounting hole. As a result, the projecting sections of the inserted section 61 formed on its two sides and the flange section 62 sandwich the rim portion of the mounting hole on front and back sides. As a result, the fastener 6 is fixed to the rim portion of the mounting hole of the plate member.

The wire harness 10A includes the nonconductive fastener 6 that is connected to the intermediate short-circuit member 2A. Therefore, in the step in which the wire harness 10A is laid in a vehicle, fixing the intermediate regions of the three electromagnetic shielding members 1 to a supporting member such as a body of the vehicle is easily achieved.

### Third Embodiment

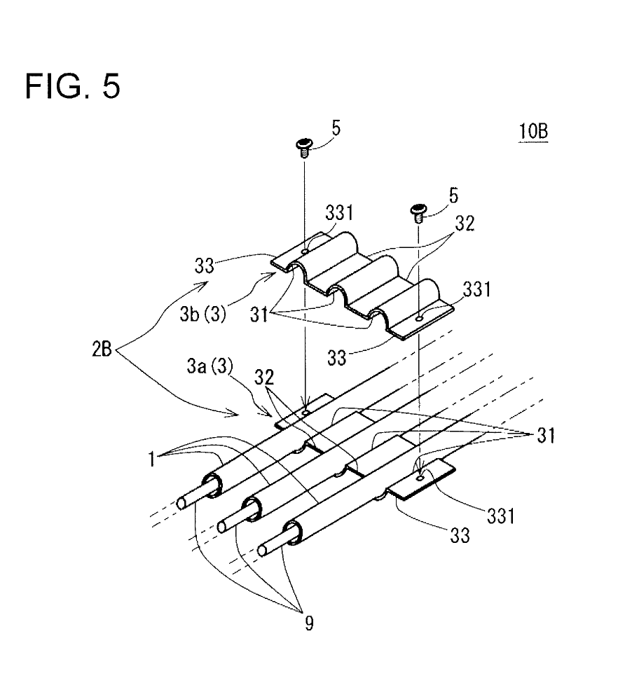

The following will describe a wire harness 10B and an intermediate short-circuit member 2B included therein according to a third embodiment with reference to FIG. 5. Note that FIG. 5 is an exploded perspective view illustrating the main part of the wire harness 10B. In FIG. 5, the same reference numerals are given to the same constituent components as those shown in FIGS. 1 to 3. Hereinafter, only differences between the wire harness 10B and the wire harness 10 will be described.

The wire harness 10B, similar to the wire harness 10, includes three power cables 9, three electromagnetic shielding members 1 that respectively surround the power cables 9, and at least one intermediate short-circuit member 2B.

The intermediate short-circuit member 2B has a configuration in which no armoring section 4 is included in the intermediate short-circuit member 2. That is, the intermediate short-circuit member 2B is just the clamping section 3. The first clamping member 3a and the second clamping member 3b constituting the clamping section 3 are connected to each other by the screws 5.

When the wire harness 10B is employed, similarly to the case in which the wire harness 10 is employed, an excessive electromagnetic induction current is prevented from flowing through the electromagnetic shielding member 1.

### OTHER EMBODIMENTS

Exemplary embodiments of the present invention have been described above. It should be noted that the above exemplary embodiments are merely examples and the present invention is not limited to the detailed embodiments. For example, in the foregoing embodiments, the clamping section 3 of each of the intermediate short-circuit members 2, 2A, and 2B is constituted by the first clamping member 3a and the second clamping member 3b that are connected to each other by the screws 5.

However, a structure is also possible in which the first clamping member 3a and the second clamping member 3b are connected to each other without connectors such as the screws 5. For example, the first clamping member 3a and the second clamping member 3b may be connected to each other by crimping, welding or the like.

Furthermore, the first clamping member 3a and the second clamping member 3b may be formed as one piece by respectively having different structures on their corresponding ends.

1. A wire harness comprising:
first, second and third power cables arranged to conduct symmetrical three-phase AC electricity;
first, second and third conductive electromagnetic shielding members arranged in parallel to each other and spaced apart from each other, each of the first, second and third conductive electromagnetic shielding members disposed surrounding respective ones of the first, second and third power cables; and
an intermediate short-circuit member arranged to electrically connect the first, second and third electromagnetic shielding members to one another in at least one intermediate region between first and second longitudinal ends of each of the electromagnetic shielding members,
the intermediate short-circuit member having a conductive member arranged to electrically connect the first, second and third electromagnetic shielding members to one another, and a nonconductive armoring section arranged to cover an outer surface of the conductive member.

2. The wire harness according to claim 1, wherein
the conductive member of the intermediate short-circuit member is a conductive clamping section arranged to clamp the first, second and third electromagnetic shielding members to each other in the intermediate region.

3. The wire harness according to claim 2, further comprising
a nonconductive fastener connected to the intermediate short-circuit member and arranged to be fixed to a rim portion of a through hole of a plate-like supporting member.

4. The wire harness according to claim 1, wherein
the intermediate short-circuit member is disposed on an outer periphery of the first, second and third conductive electromagnetic shielding members so as to surround the first, second and third conductive electromagnetic shielding members.

5. The wire harness according to claim 1, wherein
the intermediate short-circuit member is disposed between the first, second and third conductive electromagnetic shielding members in a direction in which the first, second and third conductive electromagnetic shielding members are spaced from each other.

6. The wire harness according to claim 1, wherein
the conductive member includes a first clamping section and a second clamping section which clamp the first, second and third electromagnetic shielding members to each other in the intermediate region, each of the first and second clamping sections having a plurality of grooves arranged to receive the first, second and third electromagnetic shielding members, respectively.

7. The wire harness according to claim 6, wherein
each of the first and second clamping sections further have linking sections disposed between the grooves, the plurality of grooves being spaced from each other by the linking sections.

8. The wire harness according to claim 6, wherein
each of the first and second clamping sections further have connecting sections disposed at outermost ends of the first and second clamping sections with respect to a direction in which the first, second and third conductive electromagnetic shielding members are spaced from each other, the connecting sections being arranged to fix the first and second clamping sections to each other.

9. The wire harness according to claim 6, wherein
the nonconductive armoring section includes a first armoring member and a second armoring member, the first armoring member being arranged to cover an outer surface of the first clamping section and the second armoring member being arranged to cover an outer surface of the second clamping section such that the conductive member is surrounded by the nonconductive armoring section.

10. A wire harness comprising:
a plurality of power cables arranged to conduct symmetrical three-phase AC electricity;
a plurality of conductive electromagnetic shielding members arranged in parallel to each other and spaced apart from each other, each of the plurality of conductive electromagnetic shielding members disposed surrounding respective ones of the plurality of power cables; and
an intermediate short-circuit member arranged to electrically connect the plurality of electromagnetic shielding members to one another in at least one intermediate region between first and second longitudinal ends of each of the electromagnetic shielding members,
the intermediate short-circuit member having a conductive member arranged to electrically connect the plurality of electromagnetic shielding members to one another, and a nonconductive armoring section arranged to cover an outer surface of the conductive member.
